(19) United States
(12) Patent Application Publication
(10) Pub. No.: US 2008/0050853 A1
(43) Pub. Date: Feb. 28, 2008

(54) METHOD OF FABRICATING DISPLAY SUBSTRATE

(75) Inventors: Jin-Suk SEO, Cheonan-si (KR); Sung-Man KIM, Seoul (KR); Bong-Jun LEE, Seoul (KR); Byeong-Jae AHN, Suwon-si (KR); Jong Hyuk LEE, Seoul (KR)

Correspondence Address: H.C. PARK & ASSOCIATES, PLC, 8500 LEESBURG PIKE, SUITE 7500, VIENNA, VA, 22182, US

(73) Assignee: SAMSUNG ELECTRONICS CO., LTD., Suwon-si (KR)

(21) Appl. No.: 11/843,194

(22) Filed: Aug. 22, 2007

(30) Foreign Application Priority Data
Aug. 24, 2006 (KR) 10-2006-0080699

(51) Int. Cl. H01L 21/00

(52) U.S. Cl. 438/30; 257/E31.001

(57) ABSTRACT

In a method of fabricating a display substrate, a photoresist layer pattern is formed on a substrate where a thin film transistor (TFT) is formed, and a transparent conductive layer is formed on the photoresist layer pattern. Then, the transparent conductive layer is patterned by a lift-off method to form a transparent conductive layer pattern while partially removing the photoresist layer pattern.

### CROSS-REFERENCE TO RELATED APPLICATION

This application claims priority from and the benefit of Korean Patent Application No. 10-2006-0080699, filed on Aug. 24, 2006, which is hereby incorporated by reference for all purposes as if fully set forth herein.

### BACKGROUND OF THE INVENTION

1. Field of the Invention

The present invention relates to a method of fabricating a display substrate. More particularly, the present invention relates to a method of fabricating a display substrate having a reduced number of process steps.

2. Discussion of the Background

In general, a display apparatus displaying an image includes a substrate. A plurality of pixel regions on which an image is displayed is defined in the substrate. A thin film transistor (TFT) and a pixel electrode are provided in each pixel region. The TFT and the pixel electrode are obtained by forming a conductive layer on the substrate and then patterning the conductive layer.

Various insulating layers are formed at upper and lower portions of the TFT and the pixel electrode on the substrate. Parts of the various insulating layers are patterned. Therefore, when the substrate for the display apparatus is fabricated, a plurality of patterning processes is performed on the conductive layers and the insulating layers. When the conductive layers and the insulating layers are patterned, a photo process including an exposure and development process is performed. In general, the photo process is separately performed for each layer to be patterned. As the number of layers to be patterned increases, the length of the entire process and cost thereof increases.

### SUMMARY OF THE INVENTION

The present invention provides a method of fabricating a display substrate capable of reducing the length and cost of the fabrication process.

Additional features of the invention will be set forth in the description which follows, and in part will be apparent from the description, or may be learned by practice of the invention.

The present invention discloses a method of fabricating a display substrate is provided as follows. A gate electrode is formed on a substrate divided into a first region, a second region, and a third region, and a semiconductor layer pattern is formed on the gate electrode to partially overlap the gate electrode in a plan view. A source electrode and a drain electrode spaced apart from each other are disposed on the semiconductor layer pattern, and a first photoresist layer is formed on the source electrode and the drain electrode to cover the entire surface of the substrate. A second photoresist layer is disposed on the first photoresist layer, and the first photoresist layer and the second photoresist layer are patterned to form a first photoresist layer pattern, so that the first photoresist layer and the second photoresist layers remain in the first region, the first photoresist layer remains in the second region, and the drain electrode is exposed in the third region. A transparent conductive layer is formed on the first photoresist layer pattern to cover the entire surface of the substrate. The transparent conductive layer of the first region is removed while the second photoresist layer corresponding to the first region is removed to form a transparent conductive layer pattern.

The present invention also discloses a method of fabricating a display substrate including forming a gate electrode on a substrate divided into a first region, a second region, and a third region. A semiconductor layer pattern is formed on the gate electrode to partially overlap the gate electrode in a plan view. A source electrode and a drain electrode spaced apart from each other are formed on the semiconductor layer pattern. A photoresist layer is formed on the source electrode and the drain electrode to cover the entire surface of the substrate, and the photoresist layer is patterned to form a photoresist layer pattern having a first thickness in the first region, a second thickness smaller than the first thickness in the second region, and to expose the drain electrode in the third region. A transparent conductive layer is formed on the photoresist layer pattern to cover the entire surface of the substrate. The transparent conductive layer of the first region is removed while a portion of the photoresist layer pattern having a thickness corresponding to the difference between the first thickness and the second thickness in the first region is removed to form a transparent conductive layer pattern.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1A, FIG. 2A, FIG. 3A, FIG. 4A, FIG. 5A, FIG. 6A, and FIG. 7A are plan views showing a method of fabricating a display substrate according to an exemplary embodiment of the present invention.

FIG. 1B, FIG. 2B, FIG. 3B, FIG. 4B, FIG. 5B, FIG. 6B, and FIG. 7B are sectional views taken along line I-I′ of FIG. 1A, FIG. 2A, FIG. 3A, FIG. 4A, FIG. 5A, FIG. 6A, and FIG. 7A, respectively.

FIG. 8A, FIG. 9A, FIG. 10A, FIG. 11A, FIG. 12A, and FIG. 13A are plan views showing a method of fabricating a display substrate according to another exemplary embodiment of the present invention.

FIG. 8B, FIG. 9B, FIG. 10B, FIG. 11B, FIG. 12B, and FIG. 13B are sectional views taken along line II-II′ of FIG. 8A, FIG. 9A, FIG. 10A, FIG. 11A, FIG. 12A, and FIG. 13A, respectively.

FIG. 14A, FIG. 15A, FIG. 16A, and FIG. 17A are plan views showing a method of fabricating a display substrate according to another exemplary embodiment of the present invention.

FIG. 14B, FIG. 15B, FIG. 16B, and FIG. 17B are sectional views taken along line III-III′ of FIG. 14A, FIG. 15A, FIG. 16A, and FIG. 17A, respectively.

FIG. 18 is a sectional view showing a liquid crystal display (LCD) to which a display substrate fabricated by the fabricating method according to the present invention is applied.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present.

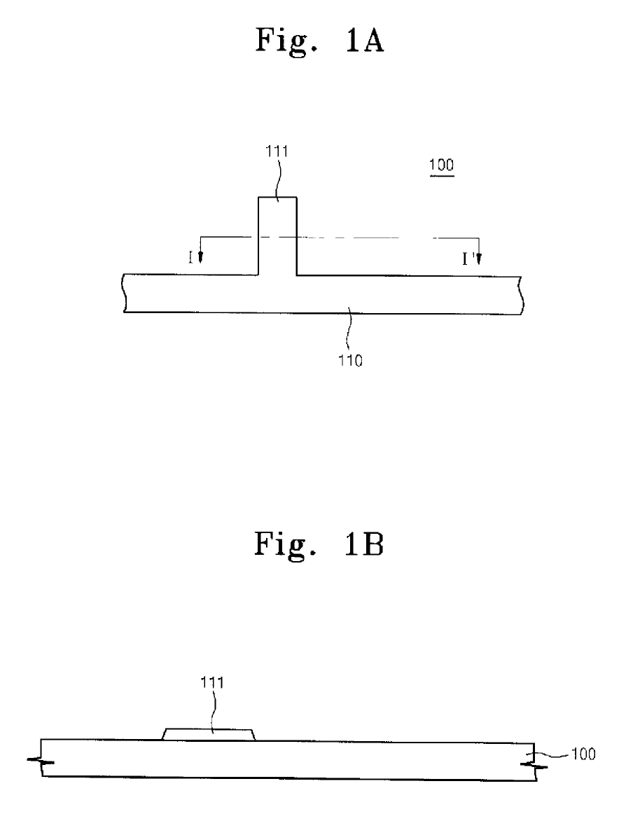

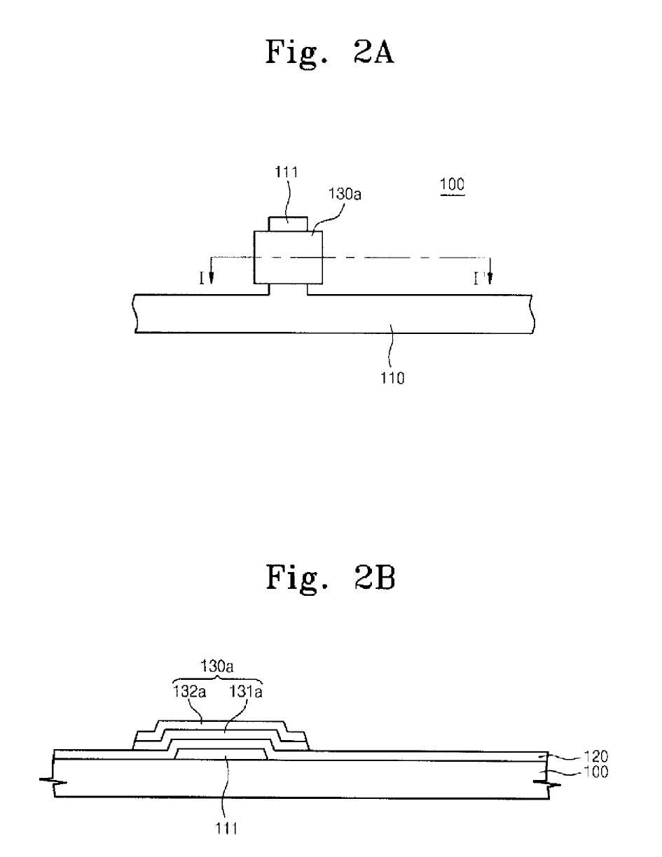

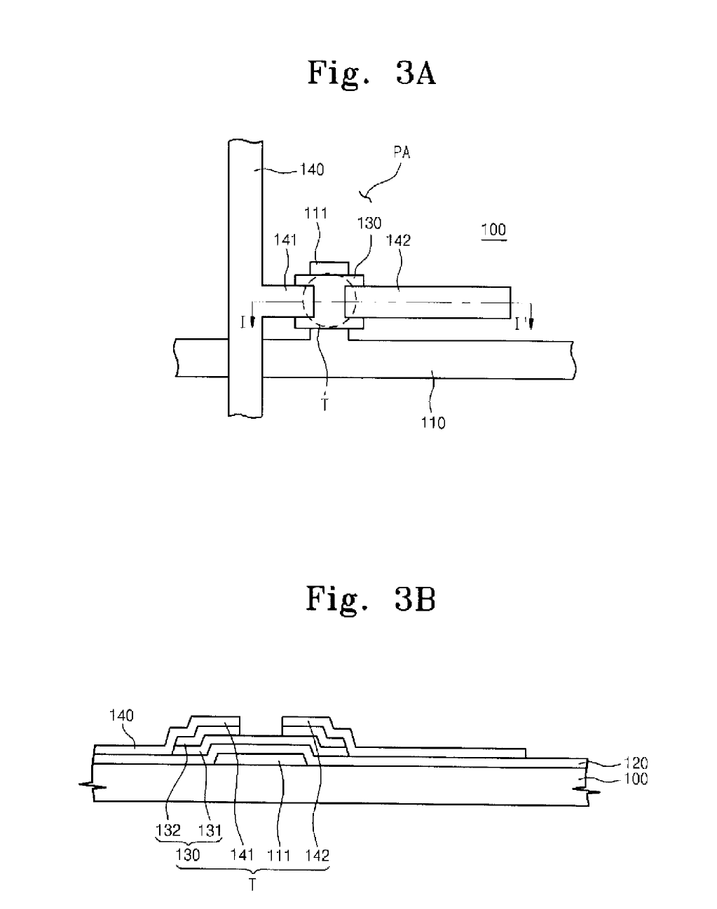

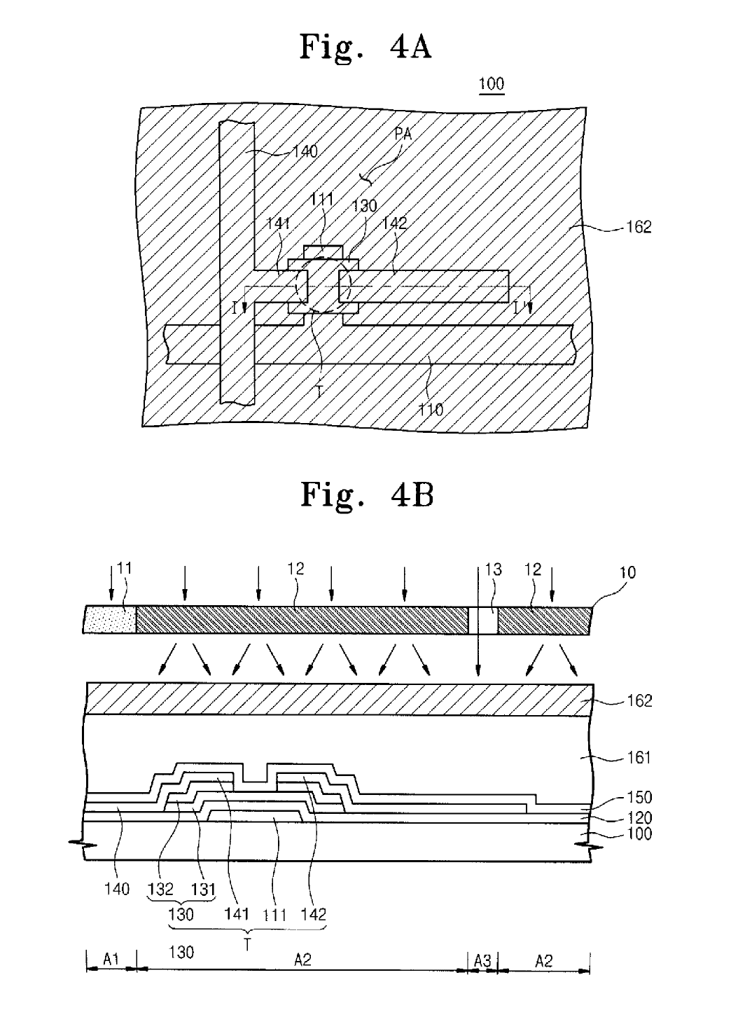

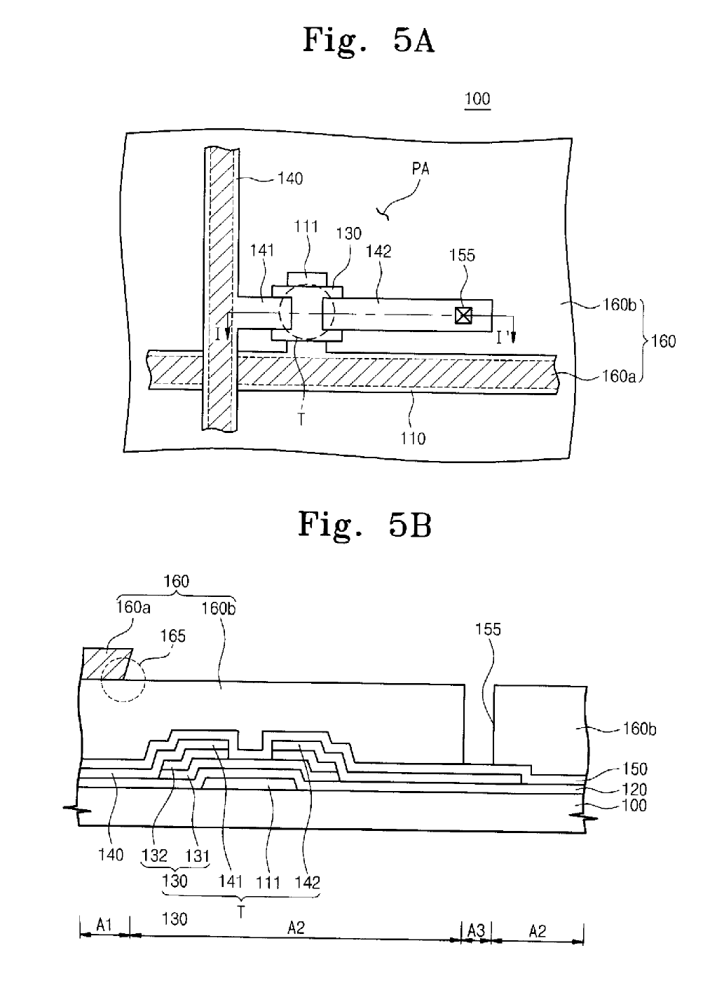

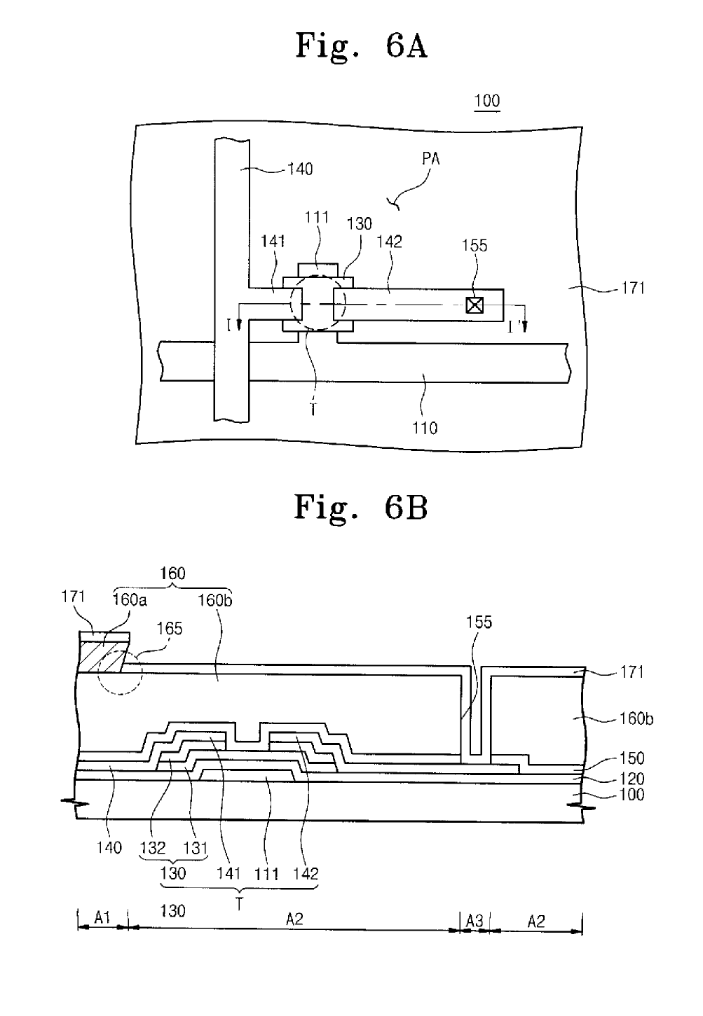

FIG. 1A, FIG. 2A, FIG. 3A, FIG. 4A, FIG. 5A, FIG. 6A, and FIG. 7A are plan views showing a method of fabricating a display substrate according to an exemplary embodiment of the present invention. FIG. 1B, FIG. 2B, FIG. 3B, FIG. 4B, FIG. 5B, FIG. 6B, and FIG. 7B are sectional views taken along line I-I′ of FIG. 5A, FIG. 2A, FIG. 3A, FIG. 4A, FIG. 5A, FIG. 6A, FIG. 7A, respectively. Since a plurality of pixel regions is defined in the display substrate and the plurality of pixel regions have the same structure, the following description will focus on one pixel region.

Referring to FIG. 1A and FIG. 1B, a gate conductive layer is formed on a substrate 100. The substrate 100 is a transparent insulating substrate that may include glass or plastic. The gate conductive layer may be formed by depositing metal through a sputtering method. The metal may include aluminum based metal such as aluminum (Al) and aluminum alloy, silver based metal such as silver (Ag) and silver alloy, copper based metal such as copper (Cu) and copper alloy, molybdenum based metal such as molybdenum (Mo) and molybdenum alloy, chrome (Cr), tantalum (Ta), and/or titanium (Ti). The gate conductive layer may be a multilayer structure including multiple metal layers having different physical properties.

The gate conductive layer is patterned to form a gate line 110 and a gate electrode 111. The patterning may be performed by forming an etching mask on the gate conductive layer and then, etching the gate conductive layer in accordance with the etching mask. In order to form the etching mask for the gate conductive layer, the gate conductive layer is coated with a photoresist layer to perform exposure and development. A first photo mask is used during the exposure.

Referring to FIG. 2A and FIG. 2B, a gate insulating layer 120 and a semiconductor layer are formed on the gate electrode 111. The gate insulating layer 120 may be formed by a plasma chemical vapor deposition method using silicon nitride to cover the entire surface of the substrate 100. The semiconductor layer may be formed by a plasma chemical vapor deposition method using amorphous silicon to cover the entire surface of the substrate 100.

The semiconductor layer is patterned to form a preliminary semiconductor layer pattern 130a. The preliminary semiconductor layer pattern 130a is prepared in the form of a dual layer including a preliminary active layer pattern 131a and a preliminary ohmic contact layer pattern 132a on the preliminary active layer pattern 131a. The preliminary ohmic contact layer pattern 132a includes impurity ions. The patterning may be performed by forming an etching mask on the semiconductor layer and then, etching the semiconductor layer in accordance with the etching mask. In order to form the etching mask for the semiconductor layer, after a photoresist layer is coated with the semiconductor layer, exposure and development are performed. A second photo mask may be used during the exposure.

Referring to FIG. 3A and FIG. 3B, a data conductive layer is formed on the preliminary semiconductor layer pattern 130a. The data conductive layer may be a single layer or a multilayer structure including metals, such as those discussed with regard to the gate conductive layer.

The data conductive layer is patterned to form a data line 140, a source electrode 141, and a drain electrode 142. The patterning may be performed by forming an etching mask on the data conductive layer and then, etching the data conductive layer in accordance with the etching mask. In order to form the etching mask for the data conductive layer, after the data conductive layer is coated with a photoresist layer, exposure and development are performed. A third photo mask is used during the exposure.

The source electrode 141 and the drain electrode 142 are spaced apart from each other on the gate electrode 111 to expose the preliminary semiconductor layer pattern 130a through the space between the source electrode 141 and the drain electrode 142. The exposed portion is etched to form a semiconductor layer pattern 130. During etching of the exposed portion, ohmic contact patterns 132 spaced apart from each other in accordance with the source electrode 141 and the drain electrode 142 are formed. Also, during etching of the exposed portion, an active pattern 131 is formed under the ohmic contact patterns 132. The top surface of the active pattern 131, having a predetermined thickness, may be removed by over-etching.

After the exposed portion is etched, a TFT T is completed and includes the gate electrode 111, the gate insulating layer 120, the semiconductor layer pattern 130, the source electrode 141, and the drain electrode 142. Also, the pixel region PA is defined by the gate line 110 and the data line 140.

Referring to FIG. 4A and FIG. 4B, a protecting layer 150 is formed on the TFT T. The protecting layer 150 may be formed by a plasma chemical vapor deposition method using an inorganic layer, such as silicon nitride, to cover the entire surface of the substrate 100. A first photoresist layer 161 and a second photoresist layer 162 are sequentially formed on the protecting layer 150. The first and second photoresist layers 161 and 162 have different components. In particular, the first photoresist layer 161 may include an organic component such as acryl resin. The first and second photoresist layers 161 and 162 may have different thicknesses such that the first photoresist layer 161 is thicker than the second photoresist layer 162. For example, the first photoresist layer 161 may have a thickness of about 4 μm to about 5 μm and the second photoresist layer 162 may have a thickness of about 0.5 μm to about 1.5 μm. The first photoresist layer 161 partially remains on the substrate 100 as an insulating layer after the process is completed. Therefore, the thickness of the first photoresist layer 161 may be determined by considering the thickness required for the layer to perform an insulating function and the thickness by which the first photoresist layer 161 is reduced in the middle of the process.

Exposure may be performed on the first and second photoresist layers 161 and 162 using a fourth photo mask 10. The fourth photo mask 10 includes a non-transmitting portion 11, an intermediate transmitting portion 12, and a transmitting portion 13. While light is wholly intercepted or transmitted by the non-transmitting portion 11 and the transmitting portion 13, respectively, light is partially transmitted by the intermediate transmitting portion 12. A slit mask or a halftone mask may be used as the fourth photo mask 10 having the intermediate transmitting portion 12.

A plurality of slits is formed in the intermediate transmitting portion 12 of the slit mask, and the amount of transmitted light may be controlled by altering the distance between the slits. In the halftone mask, the intermediate transmitting portion 12 includes a material that partially transmits light. As such, the amount of transmitted light may also be controlled by the material of the components.

The photo mask 10 is designed such that only the second photoresist layer 162 is exposed in the region corresponding to the intermediate transmitting portion 12 and the first photoresist layer 161 under the second photoresist layer 162 is not exposed. Hereinafter, for convenience of explanation, the regions of the substrate 100 are distinguished from each other in accordance with their positions, so that the region corresponding to the non-transmitting portion 11 is referred to as a first region A1, the region corresponding to the intermediate transmitting portion 12 is referred to as a second region A2, and the region corresponding to the transmitting portion 13 is referred to as a third region A3. The first region A1 may correspond to the boundary of the pixel region PA and partially or wholly covers the region in which the gate line 110 and the data line 140 are formed. The second region A2 may occupy most of the pixel region PA. The third region A3 may be limited to a predetermined region in the pixel region PA.

Referring to FIG. 5A and FIG. 5B, the first and second photoresist layers 161 and 162 are developed to form a photoresist layer pattern 160. The development may be performed by providing a developer onto the substrate 100 by a dip or spray method. The developer reacts to the exposed portions in the first and second photoresist layers 161 and 162 to remove the exposed portions.

During the development, only the second photoresist layer 162 is removed from the second region A2 and the first and second photoresist layers 161 and 162 are removed from the third region A3. Therefore, the photoresist layer pattern 160 includes a first part 160a defined by the first photoresist layer 161 remaining in the first region A1 and a second part 160b defined by the second photoresist layer 162 remaining in the first and second regions A1 and A2. Also, a contact hole 155 is formed in the third region A3 where both the first and second photoresist layers 161 and 162 are removed.

On the other hand, in the exposure process, light is perpendicularly incident onto the photo mask 10, diffracted by the photo mask 10, and output at an angle to the photo mask 10 (refer to FIG. 4B). The side surface of the first part 160a is inclined against the substrate 100 at an angle equal to that at which light is output so that an undercut 165 is formed in the lower portion of the first part 160a.

Heat treatment may be performed on the photoresist layer pattern 160. The heat treatment may be performed at about 220° C. for about one hour. The photoresist layer pattern 160 may be contracted and hardened while the heat treatment is performed. In the previous process, the second part 160b may be reduced by a predetermined thickness while the development is performed and may be reduced by about 10% through contraction during the heat treatment. Therefore, after the heat treatment, the second part 160b may haves a thickness of about 3 μm to about 4 μm.

Referring to FIG. 6A and FIG. 6B, the protecting layer 150 may etched using the photoresist layer pattern 160 as an etching mask. Since the protecting layer 150 is etched, the contact hole 155 may extend to the inside of the protecting layer 150 so that the drain electrode 142 is partially exposed in the third region A3.

A transparent conductive layer 171 is formed on the photoresist layer pattern 160. The transparent conductive layer 171 may be formed by depositing indium zinc oxide or indium tin oxide using a sputtering method. The entire surface of the substrate 100 is covered with the transparent conductive layer 171 during the deposition. The transparent conductive layer 171 is deposited on the top surface of the substrate 100, but not on the side surface of the first part 160a in the region where the undercut 165 is formed, so the transparent conductive layer 171 is cut off.

Referring to FIG. 7A and FIG. 7B, the first part 160a of the photoresist layer pattern 160 is removed. When the first part 160a is removed, the transparent conductive layer 171 deposited on the surface of the first part 160a is also removed. As a result, a transparent conductive layer pattern is formed. The transparent conductive layer pattern serves as a pixel electrode 170 in the second region A2 corresponding to the pixel region PA. Also, only the second part 160b of the first photoresist layer 161 remains in the photoresist layer pattern 160. The remaining second part 160b serves as an insulating layer to insulate the pixel electrode 170 from the TFT T under the pixel electrode 170. The insulating layer may have a significant thickness in order to prevent coupling of the pixel electrode 170 and the data line 140. In the present exemplary embodiment, the insulating layer may have a thickness of about 3 μm to about 4 μm.

The first part 160a may be removed by a chemical method or a physical method. In the chemical method, a chemical solution is provided on the entire surface of the substrate 100. The chemical solution contacts the first part 160a where the transparent conductive layer 171 is cut off by the undercut 165. The chemical solution does not react with the transparent conductive layer 171, but does react with the first photoresist layer 161 that constitutes the first part 160a to remove the first photoresist layer 161.

In the physical method, the first part 160a is removed by force with a physical member. That is, a physical member 20 is positioned at a height between that of the first part 160a and that of the second part 160b and moves while maintaining this height. As described above, the physical member 20 collides with the first part 160a, so that the first part 160a is removed by a shock in accordance with the collision. In particular, since the transparent conductive layer 171 is cut off in the region where the undercut 165 is formed, the transparent conductive layer 171 is not entirely connected in the corresponding region, and the first part 160a may be easily removed by the collision. Also, when the first photoresist layer 161 that constitutes the first part 160a and the second photoresist layer 162 that constitutes the second part 160b include materials having weak adhesiveness therebetween, the first part 160a may be easily removed.

There are no special limitations on the physical member 20 and various devices may be used. For example, a brush used to cleanse the substrate 100 may be used as the physical member 20. Also, an air knife used to remove moisture from the substrate 100 may be used as the physical member 20.

According to the above fabricating method, the insulating layer including the remaining second part 160b and the pixel electrode 170 may be formed using the same photo mask 10. Therefore, only four photo masks are used in the entire process. As the number of used photo masks is reduced, the number of exposure processes is also reduced, so that exposure may be performed only four times. In this case, the entire process time may be reduced by about 15% to about 20%, thereby improving productivity and reducing manufacturing costs.

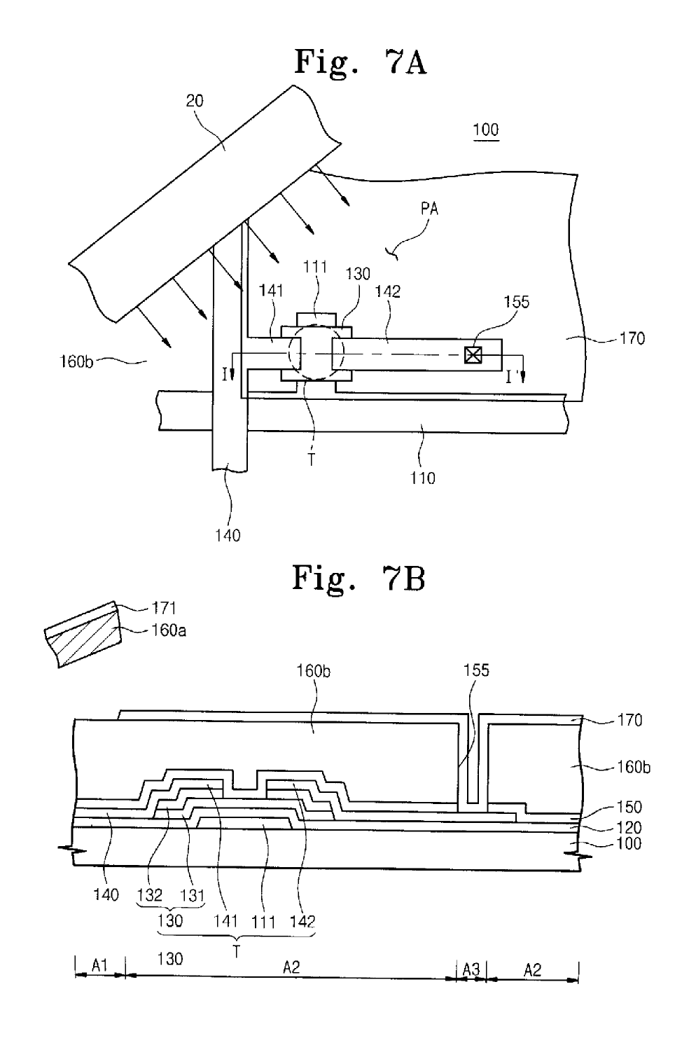

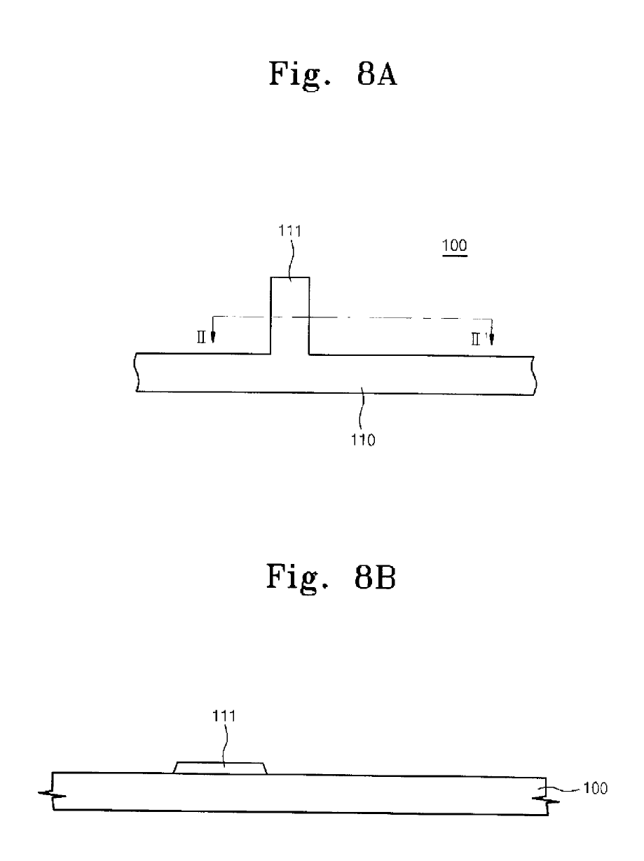

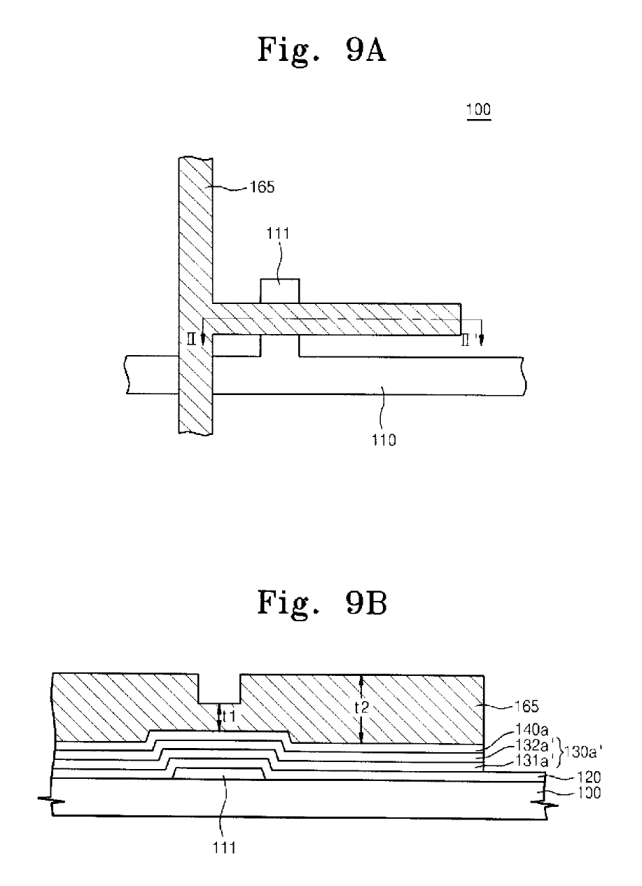

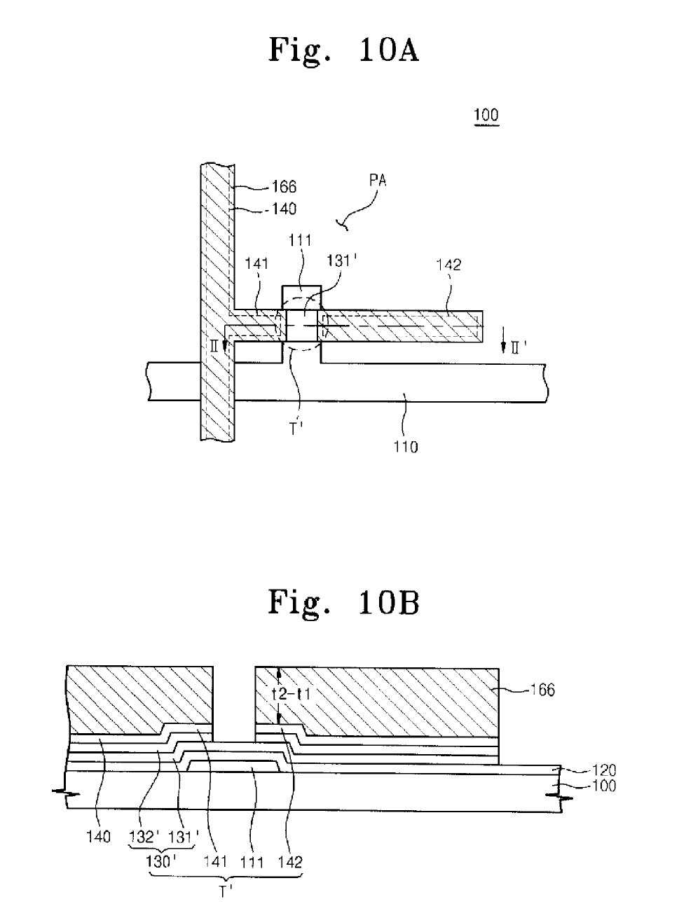

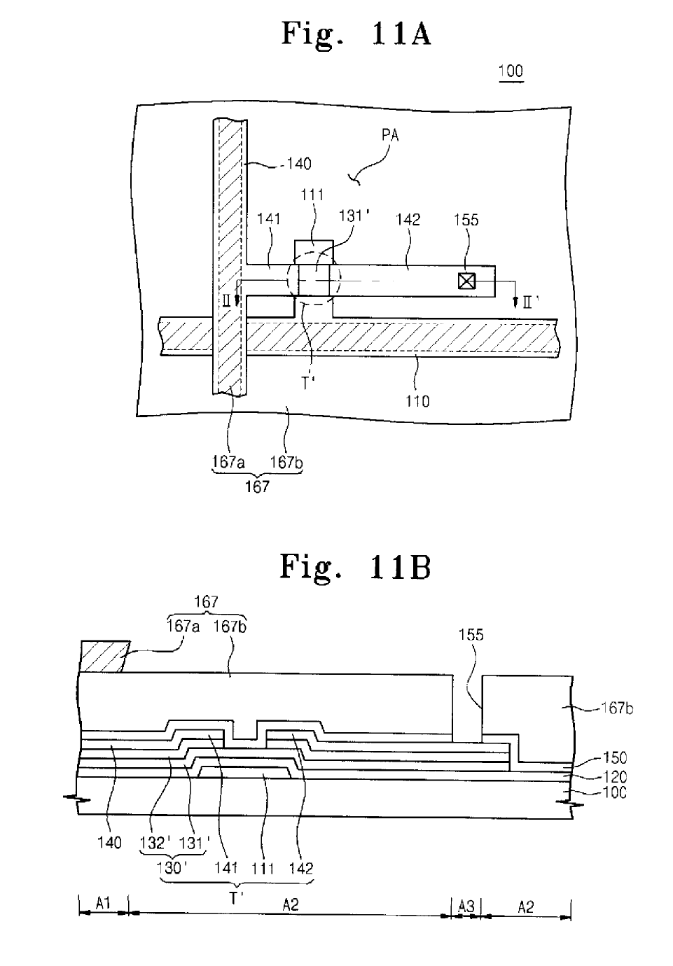

FIG. 8A, FIG. 9A, FIG. 10A, FIG. 11A, FIG. 12A, and FIG. 13A are plan views showing a method of fabricating a display substrate according to another exemplary embodiment of the present invention. FIG. 8B, FIG. 9B, FIG. 10B, FIG. 11B, FIG. 12B, and FIG. 13B are sectional views taken along line II-II′ of FIG. 8A, FIG. 9A, FIG. 10A, FIG. 11A, FIG. 12A, and FIG. 13A, respectively. According to the present exemplary embodiment, a detailed description of the parts the same as those of the first exemplary embodiment is omitted.

Referring to FIG. 8A and FIG. 8B, a gate conductive layer is formed on the substrate 100 and the gate conductive layer is patterned to form the gate line 110 and the gate electrode 111. During the patterning, after an etching mask is formed on the gate conductive layer, the gate conductive layer is etched in accordance with the etching mask. In order to form the etching mask, after the gate conductive layer is coated with a photoresist layer, exposure and development are performed. The exposure for the photoresist layer may be performed using a first photo mask.

Referring to FIG. 9A and FIG. 9B, a gate insulating layer 120, a semiconductor layer, and a data conductive layer are sequentially formed on the gate electrode 111. A first photoresist layer is formed on the data conductive layer. Exposure and development are performed on the first photoresist layer to form a first photoresist layer pattern 165. The exposure for the first photoresist layer may be performed using a second photo mask. The thickness of the first photoresist layer pattern 165 is non-uniform, so that the first photoresist layer pattern 165 includes a portion having a first thickness t1 and a portion having a second thickness t2 thicker than the first thickness t1. As described above, a slit mask or a halftone mask may be used as the photo mask during the exposure for the first photoresist layer, so that the first photoresist layer pattern 165 has different thicknesses in different regions.

The data conductive layer and the semiconductor layer are etched using the first photoresist layer pattern 165 as an etching mask. As a result, a data conductive layer pattern 140a is formed and a preliminary semiconductor layer pattern 130a′ having a dual layer structure including an active layer 131a′ and an ohmic contact layer 132a′ is formed.

Referring to FIG. 10A and FIG. 10B, a top portion of the first photoresist layer pattern 165 having a thickness equal to the first thickness t1 is removed so that a second photoresist layer pattern 166 is formed. The second photoresist layer pattern 166 has a thickness corresponding to the difference between the second thickness t2 and the first thickness t1. The portion of the first photoresist layer pattern 165 having the first thickness t1 is removed. The data conductive layer pattern 140a and the preliminary semiconductor layer pattern 130a′ of the exposed portion may be etched using the second photoresist layer pattern 166 as an etching mask.

After the etching, the data line 140 is formed. The data line 140 crosses the gate line 110 to define the pixel region PA. Also, after the etching, the source electrode 141 and the drain electrode 142 are formed and spaced apart from each other. A semiconductor layer pattern 130′ is formed under the source electrode 141 and the drain electrode 142. The semiconductor layer pattern 130′ includes an active pattern 131′ and ohmic contact patterns 132′. The active pattern 131′ overlaps the data line 140, source electrode 141, and drain electrode 142, and the ohmic contact patterns 132′ are spaced apart from each other in accordance with the source electrode 141 and the drain electrode 142. Therefore, a TFT T′ including the gate electrode 111, the semiconductor layer pattern 130′, the source electrode 141, and the drain electrode 142 is completed.

According to the present exemplary embodiment, the data conductive layer and the semiconductor layer may be patterned using one photo mask. As a result, in the structure, the data conductive layer overlaps the semiconductor layer in a plan view except for in the channel region of the TFT T′. Also, the number of photo masks required may be reduced so that the length of the overall process may also be reduced.

Referring to FIG. 11A and FIG. 11B, the protecting layer 150 is formed on the TFT T′ to cover the entire surface of the substrate 100. A photoresist layer having a dual layer structure including different components is formed on the protecting layer 150. A lower layer is formed of a transparent layer including an organic component and has a thickness of about 4 μm to about 5 μm, and an upper layer has a thickness of about 0.5 μm to about 1.5 μm. Exposure and development are performed on the photoresist layer having the dual layer structure. During the exposure, a third photo mask capable of performing slit or halftone exposure may be used. A third photoresist layer pattern 167 is formed by the development. Heat treatment is performed on the third photoresist layer pattern 167 so that the third photoresist layer pattern 167 contracts and hardens.

The third photoresist layer pattern 167 includes a first part 167a and a second part 167b. The first part 167a is the part remaining after the upper layer of the photoresist layer is patterned and the second part 167b is the part remaining after the lower layer of the photoresist layer is patterned. In the substrate 100, the part in which the first and second parts 167a and 167b exist is referred to as a first region A1 and the part in which only the second part 167b remains is referred to as a second region A2. Also, the part from which the first and second parts 167a and 167b are both removed is referred to a third region A3. The third region A3 is provided with a contact hole 155 formed therethrough.

The first region A1 commonly corresponds to the boundary of the pixel region PA and partially or wholly covers the region in which the gate line 110 and the data line 140 are formed. The second region A2 commonly occupies most of the pixel region PA. The third region A3 may be limited to a predetermined region in the pixel region PA.

Referring to FIG. 12A and FIG. 12B, the protecting layer 150 may be etched using the second photoresist layer pattern 167 as an etching mask. During to the etching process, the contact hole 155 may be extended to the protecting layer 150 in the third region A3 to expose the drain electrode 142 therethrough. The transparent conductive layer 171 is deposited on the photoresist layer pattern 167. The transparent conductive layer 171 covers the entire surface of the substrate 100 and the contact hole 155, and contacts the drain electrode 142. When the second photoresist layer pattern 167 is formed, the undercut 165 may be formed on the side surface of the first part 167a. The transparent conductive layer 171 may be partially cut off in the vicinity of the region where the undercut 165 is formed.

Referring to FIG. 13A and FIG. 13B, the first part 167a of the second photoresist layer pattern 167 having the transparent conductive layer 171 deposited thereon is removed, forming the pixel electrode 170. Also, only the second part 167b remains in the second photoresist layer pattern 167 and the remaining second part 167b acts as an insulating layer that insulates the pixel electrode 170 and the TFT T′ from each other.

The first part 167a may be removed by a chemical method or a physical method. According to the chemical method, a chemical solution that reacts with only the first part 167a is injected onto the portion where the transparent conductive layer 171 is cut off. According to the physical method, a physical member 20 moves to collide with the first part 167a. Various devices may be used as the physical member 20. For example, a brush or an air knife used to cleanse the substrate 100 may be used as the physical member 20.

According to the above-described fabricating method, only three photo masks are used for the entire process. Also, the number of exposure processes required is reduced to three. As a result, the overall process time may be reduced, thereby improving productivity and reducing manufacturing costs.

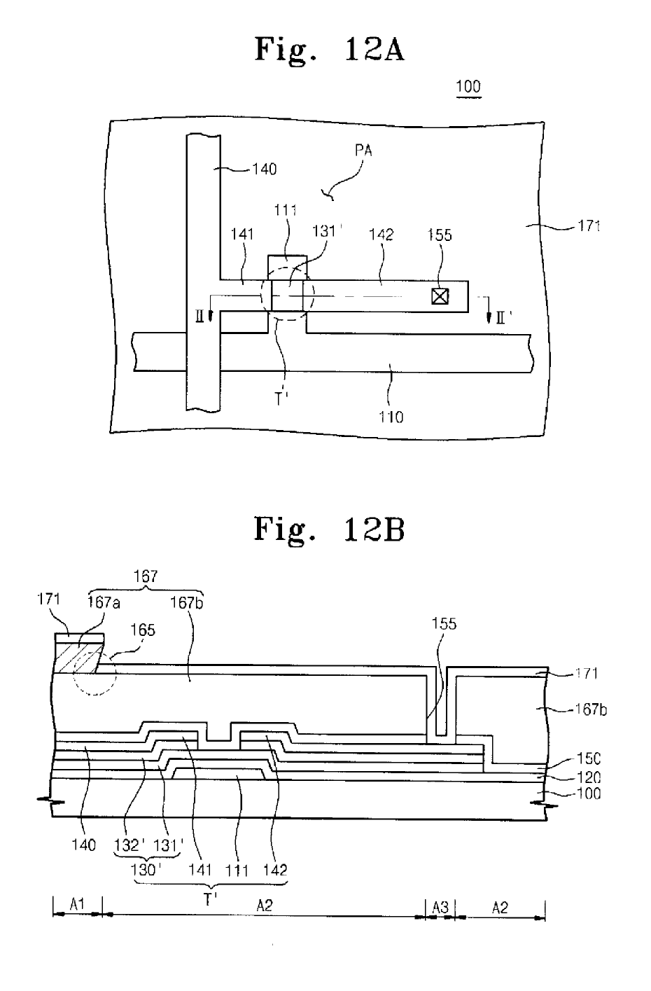

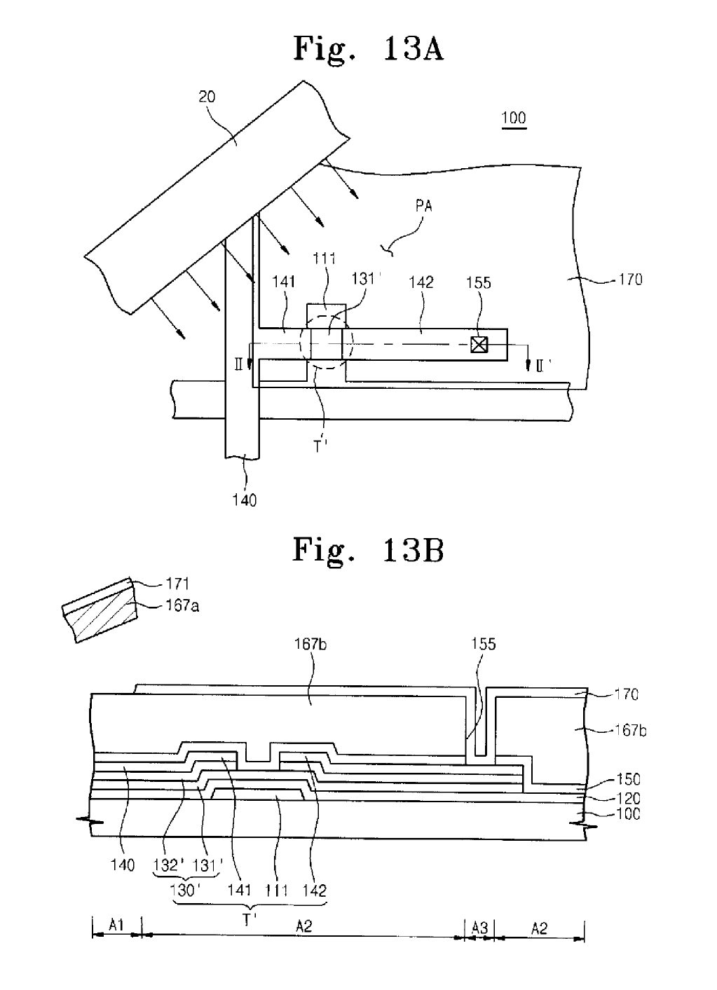

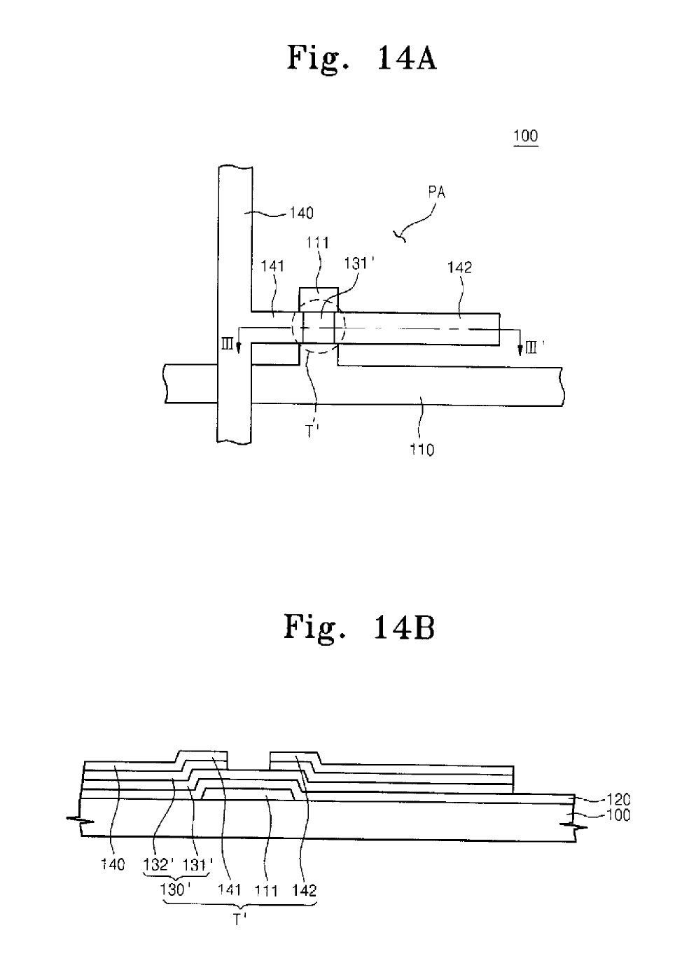

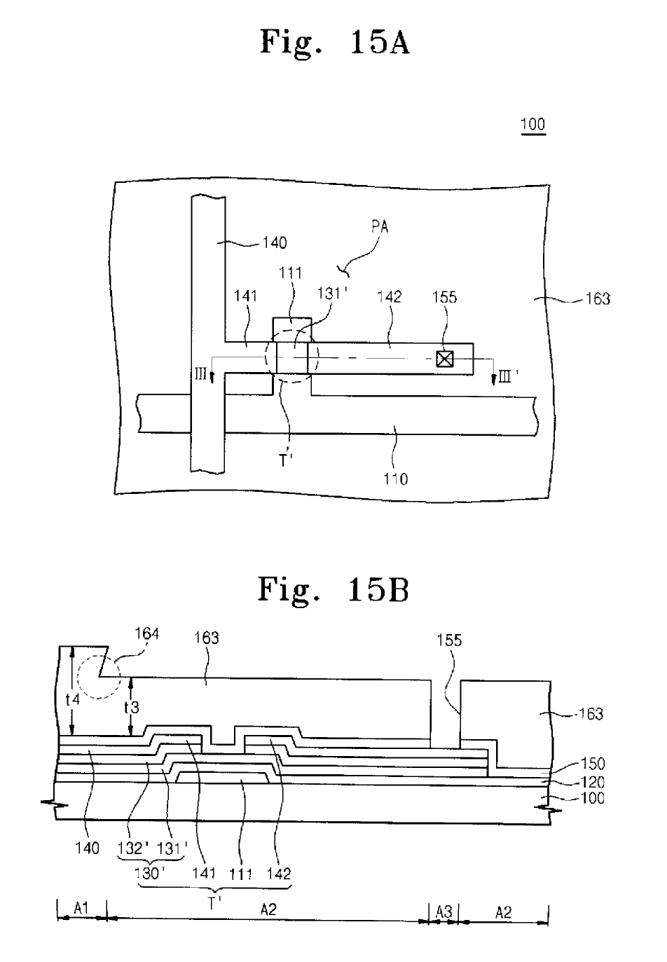

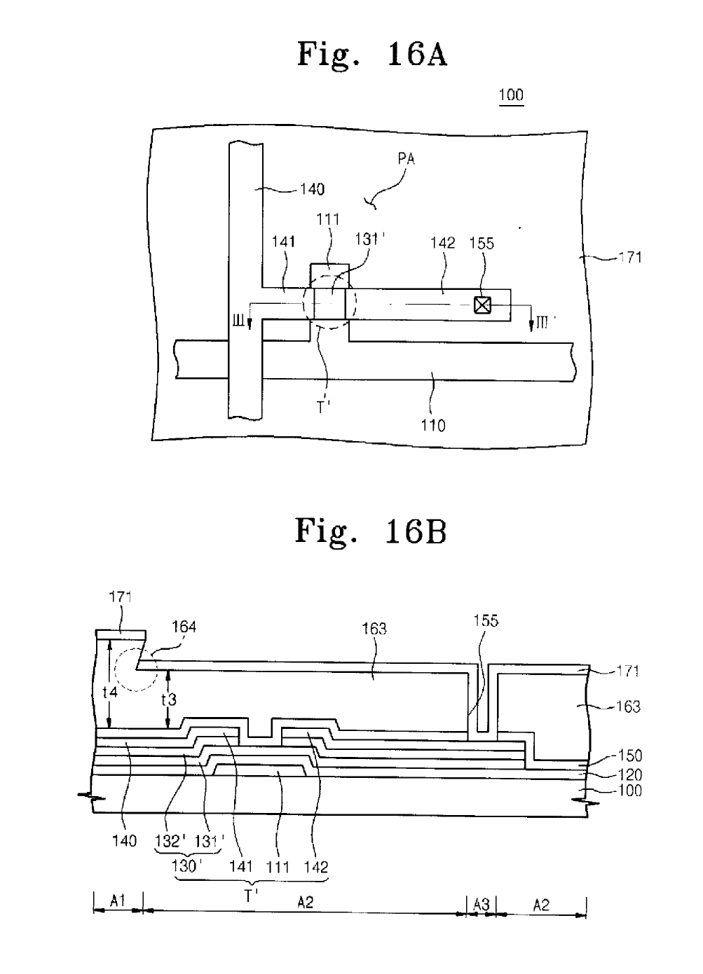

FIG. 14A, FIG. 15A, FIG. 16A, and FIG. 17A are plan views showing a method of fabricating a display substrate according to an exemplary embodiment of the present invention. FIG. 14B, FIG. 15B, FIG. 16B, and FIG. 17B are sectional views taken along line III-III′ of FIG. 14A, FIG. 15A, FIG. 16A, and FIG. 17A, respectively. According to the present exemplary embodiment, a detailed description of parts the same as those of the first and second exemplary embodiments is omitted.

Referring to FIG. 14A and FIG. 14B, a gate line 110 and a gate electrode 111 are formed on a substrate 100. A gate insulating layer 120 is formed on the gate electrode 111. A semiconductor layer pattern 130′ is formed on the gate insulating layer 120. The semiconductor layer pattern 130′ includes an active pattern 131′ and ohmic contact patterns 132′. The ohmic contact patterns 132′ include impurity ions and are spaced apart from each other on the gate electrode 111.

A data line 140, a source electrode 141, and a drain electrode 142 are formed on the semiconductor layer pattern 130′. Therefore, a TFT T′ including the gate electrode 111, the semiconductor layer pattern 130′, the source electrode 141, and the drain electrode 142 is completed. The semiconductor layer pattern 130′ and the data line 140, source electrode 141, and drain electrode 142 may be formed using the same photo mask and may overlap each other in a plan view except for in the channel region of the TFT T′. In the present exemplary embodiment, a slit mask or a halftone mask may be used as the photo mask.

Referring to FIG. 15A and FIG. 15B, a protecting layer 150 is formed on the TFT T′ and a photoresist layer is formed on the protecting layer 150. The photoresist layer may be a transparent layer including an organic component and having a thickness of about 4.5 μm to about 6.5 μm. Exposure and development are performed on the photoresist layer so that a photoresist layer pattern 163 is formed. Then heat treatment is performed on the photoresist layer pattern 163 causing the photoresist layer pattern 163 to contract and harden.

In the photoresist layer pattern 163, a predetermined region is opened so that a contact hole 155 is formed through the photoresist layer pattern 163. Also, the photoresist layer pattern 163 includes a portion having a third thickness t3 and a portion having a fourth thickness t4 larger than the third thickness t3. During the exposure for the photoresist layer, a slit mask or a halftone mask capable of performing exposure of an intermediate tone may be used, so that the photoresist layer pattern 163 has different thicknesses in different regions as described above.

In detail, in the opened portion defining the contact hole 155, light is wholly transmitted. In the portion having the fourth thickness t4, light is intercepted. In the portion having the third thickness t3, light is partially transmitted. In the substrate 100, the portion having the fourth thickness t4 is referred to as a first region A1. The portion having the third thickness t3 is referred to as a second region A2. The portion corresponding to the contact hole 155 is referred to as a third region A3. The first region A1 commonly corresponds to the boundary of the pixel region PA and partially or wholly overlaps the region where the gate line 110 and the data line 140 are formed. The second region A2 commonly occupies most of the pixel region PA. The third region A3 may be limited to a predetermined region in the pixel region PA.

Referring to FIG. 16A and FIG. 16B, the protecting layer 150 may be etched using the photoresist layer pattern 163 as an etching mask. During etching, the contact hole 155 is extended in the third region A3 so that the drain electrode 142 is exposed through the contact hole 155.

The transparent conductive layer 171 is deposited on the photoresist layer pattern 163. The transparent conductive layer 171 covers the entire surface of the substrate 100 and contacts the drain electrode 142 through the contact hole 155. When the photoresist layer pattern 163 is formed, an undercut 164 may be formed on the side surface of the portion having the fourth thickness t4. The transparent conductive layer 171 may be partially cut off in the vicinity of the region where the undercut 164 is formed.

Referring to FIG. 17A and FIG. 17B, the photoresist layer pattern 163 formed in the first region A1 is partially removed. The removed portion protrudes a distance equal to the difference between the fourth thickness t4 and the third thickness t3. When the protruding portion is removed, the transparent conductive layer 171 deposited on the surface of the protruding portion is also removed, forming the pixel electrode 170. Also, the photoresist layer pattern 163 with the third thickness t3 remains and acts as an insulating layer to insulate the pixel electrode 170 and the TFT T′ from each other. After the insulating layer is initially formed with a thickness of about 4.5 μm to about 6.5 μm, a portion of the insulating layer having a thickness equal to the difference between the fourth thickness t4 and the third thickness t3 is removed and the remaining portion is hardened during the heat treatment, so that the insulating layer finally has a thickness of about 3 μm to about 4 μm.

The protruding portion may be removed by a physical method. According to the physical method, a physical member 20 moves to collide with the protruding portion. Various devices, such as a brush and an air knife, may be used as the physical member 20.

According to the above-described fabricating method, only three photo masks may be used for the entire process. Accordingly, the required number of exposure processes is reduced to three. As a result, the overall process time may be reduced, thereby improving productivity and reducing the manufacturing costs.

Hereinafter, the structure of a liquid crystal display (LCD) apparatus to which a display substrate fabricated according to the above fabricating method may be applied will be schematically described.

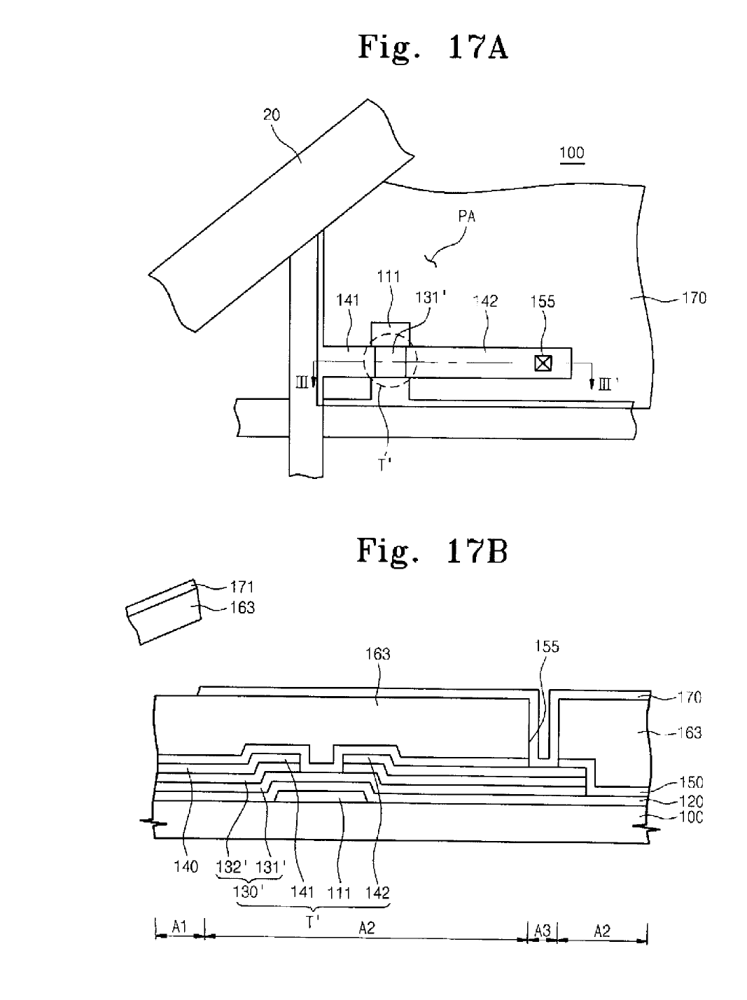

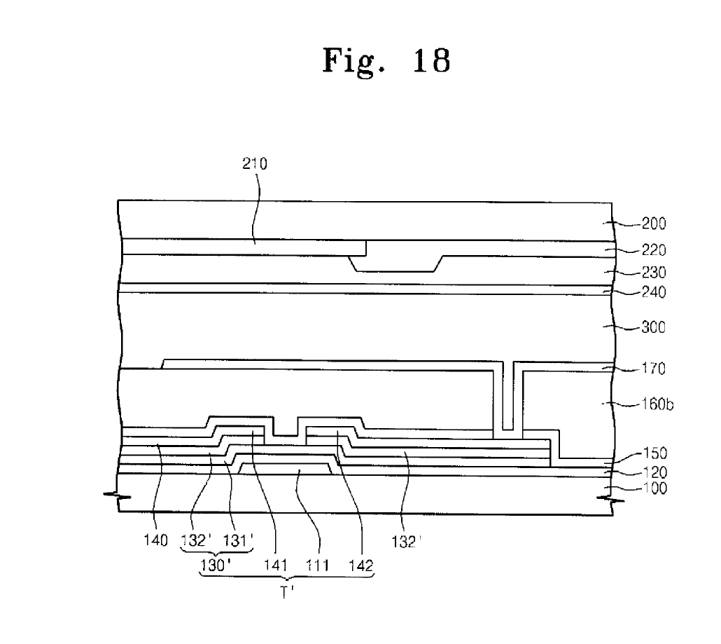

FIG. 18 is a sectional view showing an exemplary embodiment of a liquid crystal display (LCD) to which the display substrate fabricated by the fabricating method according to the present invention may be applied.

Referring to FIG. 18, two substrates 100 and 200 and a liquid crystal layer 300 interposed between the two substrates 100 and 200 are provided. In order to distinguish the two substrates 100 and 200 from each other, a lower substrate is referred to as the first substrate 100 and an upper substrate is referred to as the second substrate 200. A display substrate fabricated by the above-described fabricating method is used as the first substrate 100. The display substrate fabricated in accordance with the exemplary embodiment is shown in FIG. 18 and the same reference numerals are used. A detailed description of the same parts in relation to the first substrate 100 will be omitted.

A gate electrode 111, a gate insulating layer 120, a semiconductor layer pattern 130′, a data line 140, a source electrode 141, a drain electrode 142, a protecting layer 150, a insulating layer 160b, and a pixel electrode 170 are formed on the first substrate 100.

A light-blocking layer pattern 210, a color filter 220, an overcoat layer 230, and a common electrode 240 are formed on the second substrate 200. The light-blocking layer pattern 210 prevents light from being transmitted through the boundary of the pixel region. The color filter 220 includes red, green, and blue filters corresponding to the three primary colors of light to display a color image. The overcoat layer 230 protects the color filter 220 and planarizes the surface of the second substrate 200. The common electrode 240 is formed corresponding to the pixel electrode 170.

When the LCD operates, a signal corresponding to image information is transmitted to the data line 140 so that a data voltage is applied to the pixel electrode 170. A uniform common voltage is applied to the common electrode 240. An electric field is formed in the liquid crystal layer 300 due to the voltage difference between the data voltage and the common voltage.

The liquid crystal molecules that constitute the liquid crystal layer 300 have dielectric constant anisotropy and the alignment of the liquid crystal molecules varies according to the electric field. The liquid crystal molecules have refractive index anisotropy and thus, light transmittance varies in accordance with the alignment of the liquid crystal molecules. Therefore, when light is provided to the liquid crystal layer 300, the light passes through the liquid crystal layer 300 in accordance with the light transmittance corresponding to the alignment of the liquid crystal to display the corresponding image.

During the above operation, the data voltage may be distorted due to coupling between the data line 140 and the pixel electrode 170. The insulating layer 160b includes a transparent dielectric layer having a low dielectric constant and a thickness of about 3 μm to about 4 μm to separate the data line 140 and the pixel electrode 170 and thus, to prevent the data voltage from being distorted. In order to form the insulating layer 160b, exposure and development processes using a photo mask may be additionally performed. According to the above exemplary embodiments, the insulating layer 160b and the pixel electrode 170 are formed using the same photo mask so that the manufacturing processes and the costs thereof may be reduced.

According to the above exemplary embodiments, the number of processes required for the fabrication of a liquid crystal display may be reduced since the insulating layer and the pixel electrode may be formed using the same photo mask. Also, as the number of processes is reduced, the manufacturing costs may be reduced.

It will be apparent to those skilled in the art that various modifications and variations can be made in the present invention without departing from the spirit or scope of the invention. Thus, it is intended that the present invention cover the modification and variations of this invention provided they come within the scope of the appended claims and their equivalents.

What is claimed is:

1. A method of fabricating a display substrate, the method comprising:
forming a gate electrode on a substrate divided into a first region, a second region, and a third region;
forming a semiconductor layer pattern on the gate electrode to partially overlap the gate electrode in a plan view;
forming a source electrode and a drain electrode, which are spaced apart from each other, on the semiconductor layer pattern;
forming a first photoresist layer on the source electrode and the drain electrode to cover an entire surface of the substrate;
forming a second photoresist layer on the first photoresist layer;
patterning the first photoresist layer and the second photoresist layer to form a first photoresist layer pattern such that the first photoresist layer and the second photoresist layer remain in the first region, the first photoresist layer remains in the second region, and the first photoresist layer and the second photoresist layer are removed in the third region;
forming a transparent conductive layer to cover an entire surface of the substrate; and
removing the transparent conductive layer of the first region while removing the second photoresist layer corresponding to the first region to form a transparent conductive layer pattern.

2. The method of claim 1, wherein the first region corresponds to a boundary between pixel regions defined in the substrate, and the second region corresponds to the pixel regions.

3. The method of claim 1, further comprising heat-treating the first photoresist layer pattern after patterning the first photoresist layer and the second photoresist layer.

4. The method of claim 1, wherein the second photoresist layer remaining in the first region is physically or chemically removed.

5. The method of claim 1, wherein the second photoresist layer remaining in the first region is removed by a physical member that moves at a height corresponding to a side surface of the second photoresist layer.

6. The method of claim 5, wherein the physical member comprises a brush used to clean the substrate.

7. The method of claim 1, wherein an undercut is formed in a lower portion of the second photoresist layer remaining in the first region.

8. The method of claim 7, wherein the transparent conductive layer comprises a gap in the region where the undercut is formed.

9. The method of claim 1, wherein the first photoresist layer comprises an organic layer.

10. The method of claim 9, wherein the first photoresist layer has a thickness of about 4 μm to about 5 μm, and the second photoresist layer has a thickness of about 0.5 μm to about 1.5 μm.

11. The method of claim 10, further comprising forming an inorganic protecting layer between the source electrode and the drain electrode and the first photoresist layer.

12. The method of claim 11, further comprising etching the inorganic protecting layer using the first photoresist layer pattern as an etching mask to expose the drain electrode in the third region.

13. The method of claim 1, wherein patterning the first photoresist layer and the second photoresist layer comprises exposing and developing the first photoresist layer and the second photoresist layer, wherein the second photoresist layer is slit-exposed or halftone-exposed in the second region during the exposure process.

14. The method of claim 1, further comprising forming a gate insulating layer on an entire surface of the substrate to cover the entire surface of the substrate between the gate electrode and the semiconductor layer pattern.

15. The method of claim 14, wherein forming the semiconductor layer pattern and forming the source electrode and the drain electrode on the semiconductor layer pattern comprises:
forming a semiconductor layer and a data conductive layer on the gate insulating layer;
forming a second photoresist layer pattern on the semiconductor layer to expose the data conductive layer, wherein the second photoresist layer pattern has a first thickness and a second thickness thicker than the first thickness in different regions;
removing the data conductive layer exposed by the second photoresist layer pattern and the semiconductor layer corresponding to the removed data conductive layer;
uniformly removing a portion of the second photoresist layer pattern by the first thickness to form a third photoresist layer pattern;
removing the data conductive layer exposed by the third photoresist layer pattern to form the source electrode and the drain electrode; and
removing portions of the semiconductor layer exposed between the source electrode and the drain electrode to form the semiconductor layer pattern.

16. A method of fabricating a display substrate, the method comprising:
forming a gate electrode on a substrate divided into a first region, a second region, and a third region;
forming a semiconductor layer pattern on the gate electrode to partially overlap the gate electrode in a plan view;
forming a source electrode and a drain electrode spaced apart from each other on the semiconductor layer pattern;
forming a photoresist layer on the source electrode and the drain electrode to cover an entire surface of the substrate;
patterning the photoresist layer to form a photoresist layer pattern having a first thickness in the first region, and a second thickness smaller than the first thickness in the second region, wherein the drain electrode is exposed in the third region;
forming a transparent conductive layer on the photoresist layer pattern to cover an entire surface of the substrate; and
removing the transparent conductive layer of the first region while removing a portion of the photoresist layer pattern having a thickness corresponding to the difference between the first thickness and the second thickness in the first region to form a transparent conductive layer pattern.

17. The method of claim 16, wherein the first region corresponds to a boundary between pixel regions defined in the substrate, and the second region corresponds to the pixel regions.

18. The method of claim 16, wherein the photoresist layer pattern is removed by a physical member that moves at a height between the first thickness and the second thickness in the first region.

19. The method of claim 16, wherein the photoresist layer comprises an organic layer.

20. The method of claim 19, wherein the photoresist layer has a thickness of about 4.5 μm to about 6.5 μm.
